(19) United States
(12) Patent Application Publication
(10) Pub. No.: US 2025/0273628 A1
(43) Pub. Date: Aug. 28, 2025

(54) MULTICHIP PACKAGES FORMED IN STABLE STRUTURE AND METHOD OF FORMING THE SAME

(71) Applicant: SK hynix Inc., Icheon-si Gyeonggi-do (KR)

(72) Inventor: Dong Keun KIM, Icheon-si Gyeonggi-do (KR)

(73) Assignee: SK hynix Inc., Icheon-si Gyeonggi-do (KR)

(21) Appl. No.: 18/731,924

(22) Filed: Jun. 3, 2024

(30) Foreign Application Priority Data
Feb. 28, 2024 (KR) 10-2024-0029200

(51) Int. Cl. H01L 25/065; H01L 23/13; H01L 23/492; H01L 23/498

(52) U.S. Cl. CPC H01L 25/0657; H01L 23/13; H01L 23/492; H01L 23/49816; H01L 2225/06506; H01L 2225/0651; H01L 2225/06524; H01L 2225/06562

(57) ABSTRACT

A multichip package includes a substrate connected to a plurality of solder balls including a first solder ball, a first chip stacked over or on the substrate, a second chip stacked over or on the first chip and including a first overhang not supported by the first chip, and a support structure supporting the first overhang and connected to the first solder ball that provides an external electrical connection to the substrate for a voltage external to the substrate.

### CROSS-REFERENCE TO RELATED APPLICATIONS

The present application claims priority under 35 U.S.C. § 119 (a) to Korean Patent Application No. 10-2024-0029200, filed in the Korean Intellectual Property Office, on Feb. 28, 2024, which application is incorporated herein by reference in its entirety.

### BACKGROUND

### 1. Technical Field

The present disclosure generally relates to a multichip package formed in a stable structure with respect to physical deformation and heat treatment and a method of forming the same.

### 2. Related Art

Recently, as the use of portable devices such as smartphones, tablets, and wearable devices has increased, multichip packages that can demonstrate powerful performance while being smaller and lighter are being widely used. The multichip package is formed by stacking and combining multiple chips in a single package, thereby optimizing performance by strengthening interconnectivity between chips and increasing cost efficiency by increasing integration.

### SUMMARY

According to an embodiment, the present disclosure may provide a multichip package including a substrate connected to a plurality of solder balls including a first solder ball, a first chip stacked over the substrate, a second chip stacked over the first chip and including a first overhang by not supported by the first chip, and a support structure supporting the first overhang and connected to the first solder ball that provides an external electrical connection to the substrate for a voltage external to the substrate.

According to an embodiment, the present disclosure may provide a multichip package including a substrate connected to a plurality of solder balls including a first solder ball, a first chip stacked over the substrate, a second chip stacked over the first chip and including a first overhang not supported by the first chip, and a support structure supporting the first overhang and connected to the first solder ball that provides an external electrical connection for a device external to the substrate.

According to an embodiment, the present disclosure may provide a multichip package including a substrate connected to a plurality of solder balls including a first solder ball and a second solder ball, a first chip stacked over the substrate, a second chip stacked over the first chip and including a first overhang not supported by the first chip, a third chip stacked over the second chip and including a second overhang not supported by the second chip, a first support structure supporting the first overhang and connected to the first solder ball that provides a first external electrical connection for the substrate, and a second support structure supporting the second overhang and connected to the second solder ball that provides a second external electrical connection for the substrate.

According to an embodiment, the present disclosure may provide a multichip package including a substrate connected to a plurality of solder balls including a first solder ball and a second solder ball, a first chip stacked over the substrate, a second chip stacked over the first chip and including a first overhang not supported by the first chip, a third chip stacked over the second chip and including a second overhang not supported by the second chip, a fourth chip stacked over the third chip and including a third overhang not supported by the third chip, a first support structure supporting the first overhang and the second overhang and connected to the first solder ball that provides an external electrical connection to the substrate for a first voltage, and a second support structure supporting the third overhang and connected to the second solder ball that provides an external electrical connection to the substrate for a second voltage.

According to an embodiment, the present disclosure may provide a method of forming a multichip package. The method may include preparing a substrate connected to a plurality of solder balls, forming a support structure over the substrate, wherein the support structure is connected an external electrical connection for the substrate, stacking a first chip over the substrate, and stacking a second chip over the first chip and the support structure. The second chip may be stacked over the first chip such that an overhang not supported by the first chip is supported by the support structure.

A multichip package comprising a substrate; a first chip stacked over the substrate; a second chip stacked over the first chip, wherein the second chip is offset from the first chip in a first direction resulting in an overhang; and a support structure disposed between the overhang and the substrate and electrically connected to an external electrical connection for the substrate.

### BRIEF DESCRIPTION OF THE DRAWINGS

FIG. 1 illustrates a configuration of a multichip package according to an embodiment of the present disclosure.

FIG. 2 and FIG. 3 illustrate top and bottom views, respectively, of a plurality of chips and a support structure according to an embodiment.

FIG. 4 and FIG. 5 illustrate top and bottom views, respectively, of a plurality of chips and support structures according to an embodiment.

FIG. 6 illustrates a configuration of a multichip package according to an embodiment of the present disclosure.

FIG. 7 illustrates a configuration of a multichip package according to an embodiment of the present disclosure.

FIG. 8 illustrates a configuration of a multichip package according to an embodiment of the present disclosure.

FIG. 9 illustrates a configuration of a multichip package according to an embodiment of the present disclosure.

FIG. 10 through FIG. 13 illustrate views of a multichip package formed utilizing a method of forming a multichip package according to an embodiment of the present disclosure.

### DETAILED DESCRIPTION

In the following description, “an example” and “another example” may refer to an embodiment in which the configuration, method, and technical features of the disclosure are specified. The configuration, method, and technical features of the disclosure described in one embodiment may be combined with the configuration, method, and technical feature of the disclosure described in another embodiment to form another embodiment.

Terms such as “top,” “bottom,” “over,” “above,” “below,” “X direction,” “y direction,” “Z direction,” and other terms implying specific spatial relationship and/or orientation are utilized only for ease of description or reference to a drawing and are not otherwise limiting. The cross-hatching throughout the figures illustrates corresponding or similar areas between the figures rather than indicating the materials for the areas.

In the description, when an element included in an embodiment is described in singular form, the element may be interpreted to include a plurality of elements performing the same or similar functions.

Terms such as “first” and “second” are used to distinguish between various elements and do not imply size, order, priority, or importance of the elements. For example, a first element may be named as a second element in one example, and the second element may be named as a first element in another example.

When one element is identified as “connected” to another element, the elements may be connected directly or through an intervening element between the elements. When two elements are “directly connected” indicates that one element is directly connected to another element without an intervening element.

Similar reference numerals refer to similar devices throughout the specification. Even though a reference numeral is not mentioned with reference to a drawing, the reference numeral is mentioned with reference to another drawing. A reference numeral may be shown in one or more drawings.

The present disclosure is described in more detail through examples. These examples are provided only for convenience in illustrating and describing the present disclosure, and the scope of the present disclosure is not limited by these examples.

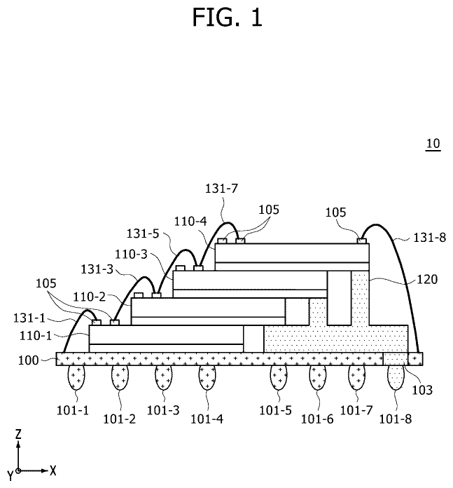

FIG. 1 illustrates a configuration of a multichip package 10 according to an embodiment of the present disclosure.

As shown in FIG. 1, the multichip package 10 includes a substrate 100, a first chip 110-1, a second chip 110-2, a third chip 110-3, a fourth chip 110-4, and a support structure 120.

The substrate 100 is supplied with a voltage through any of the solder balls 101-1 through 101-7, for example, a voltage from a source external to the multichip package 10. The substrate 100 includes a connection structure 103 connected to a solder ball 101-8. The substrate 100 may be connected to a ground voltage, for example, through the solder ball 101-8. One or more of the solder balls provides an external electrical connection for the substrate 100, for example, to a voltage, a ground voltage, or device external to the multichip package 10. The substrate 100 may be connected to devices external to the multichip package 10 such as a cooler or heat sink, an electrostatic discharge (ESD) protection device, and the like.

The first chip 110-1 is stacked over or on the substrate 100. The first chip 110-1 is electrically connected to the substrate 100 through bonding wire 131-1. The second chip 110-2 is stacked over or on the first chip 110-1. An overhang occurs because the second chip 110-2 is offset from the first chip 110-1 in an X direction, where a portion of the second chip 110-2 is not supported by the first chip 110-1 in a Z direction. The second chip 110-2 is electrically connected to the first chip 110-1 through bonding wire 131-3. The third chip 110-3 is stacked over or on the second chip 110-2. An overhang occurs because the third chip 110-3 is offset from the second chip 110-2 in the X direction, where a portion of the third chip 110-3 is not supported by the second chip 110-2 in the Z direction. The third chip 110-3 is electrically connected to the second chip 110-2 through bonding wire 131-5. The fourth chip 110-4 is stacked over or on the third chip 110-3. An overhang occurs because the fourth chip 110-4 is offset from the third chip 110-3 in the X direction, where a portion of the fourth chip 110-4 is not supported by the third chip 110-3 in the Z direction. The fourth chip 110-4 is electrically connected to the third chip 110-3 through bonding wire 131-7. The fourth chip 110-4 is electrically connected to the substrate 100 through bonding wire 131-8.

The chips 110-1, 110-2, 110-3, and 110-4 are stacked in the Z direction. An overhang of the second chip 110-2, an overhang of the third chip 110-3, and an overhang of the fourth chip result from offset stacking of the first chip 110-1, the second chip 110-2, the third chip 110-3, and the fourth chip 110-4.

The support structure 120 is disposed or connected between the substrate 100 and the second chip 110-2, the third chip 110-3, and the fourth chip 110-4 to support the overhang of each of the second chip 110-2, the third chip 110-3, the fourth chip 110-4. The support structure 120 supports the overhang where the second chip 110-2 is not supported by the first chip 110-1 in a region between the second chip 110-2 and the substrate 100. The support structure 120 supports the overhang where the third chip 110-3 is not supported by the second chip 110-2 in a region between the third chip 110-3 and the substrate 100. The support structure 120 supports the overhang where the fourth chip 110-4 is not supported by the third chip 110-3 in a region between the fourth chip 110-4 and the substrate 100. The support structure 120 supports the overhang of each of the second chip 110-2, the third chip 110-3, and the fourth chip 110-4, such that physical deformation of the second chip 110-2, the third chip 110-3, and the fourth chip 110-4 due to the overhang of the second chip 110-2, the overhang of the third chip 110-3, and the overhang of the fourth chip 110-4 may be reduced or prevented.

The support structure 120 is connected to the solder ball 101-8 through the connection structure 103. The support structure 120 and the connection structure 103 may be advantageously formed of a highly conductive material that conducts heat and electricity well. Each of the second chip 110-2, the third chip 110-3, and the fourth chip 110-4 may be connected to a ground voltage to be grounded through the support structure 120, the connection structure 103, and the solder ball 101-8. Each of the second chip 110-2, the third chip 110-3, and the fourth chip 110-4 may be connected to a cooler or a heat sink through the support structure 120, the connection structure 103, and the solder ball 101-8, such that heat generated by each of the first chip 110-1, the second chip 110-2, the third chip 110-3, and the fourth chip 110-4 is dissipated outside the multichip package 10.

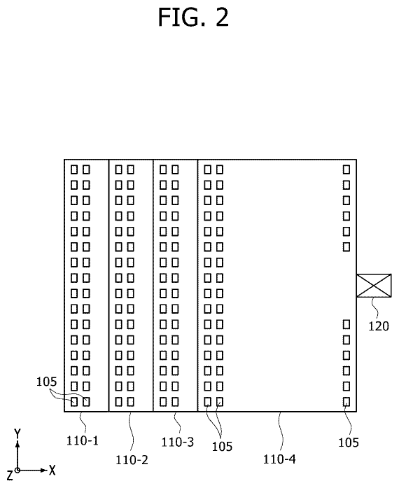

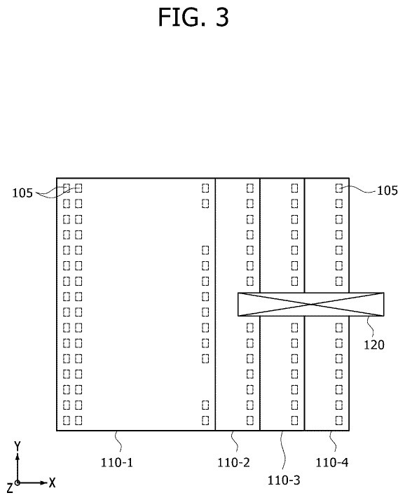

FIG. 2 and FIG. 3 illustrate top and bottom views, respectively, of a plurality of chips and a support structure 120, for example, as shown in the multichip package 10 of FIG. 1. FIG. 2 shows a top view in the Z direction of the plurality of stacked chips 110-1, 110-2, 110-3, and 110-4 and the support structure 120. FIG. 3 shows a bottom view in the Z direction of the plurality of stacked chips 110-1, 110-2, 110-3, and 110-4 and the support structure 120.

Referring to FIG. 2 and FIG. 3, a plurality of connection structures 105 among the first chip 110-1, second chip 110-2, the third chip 110-3, and the fourth chip 110-4 are illustrated. As shown in FIG. 2, a section of the support structure 120 extends beyond the fourth chip 110-4 in the X direction and is connected to the solder ball 101-8 through the connection structure 103 of the substrate 100 as shown in FIG. 1. As shown in FIG. 3, the support structure 120 supports the overhang of each of the second chip 110-2, the third chip 110-3, and the fourth chip 110-4. A section of the support structure 120 extends beyond the fourth chip 110-4 in the X direction and is connected to the solder ball 101-8 through the connection structure 103 of the substrate 100 as shown in FIG. 1. The support structure 120 supports the overhang of the second chip 110-2, the overhang of the third chip 110-3, and the overhang of the fourth chip 110-4 to prevent or reduce physical deformation of the second chip 110-2, the third chip 110-3, and the fourth chip 110-4, and may be grounded or may be connected to a cooler or a heat sink through the solder ball 101-8 to dissipate the heat generated by the first chip 110-1, second chip 110-2, third chip 110-3, and fourth chip 110-4 outside the multichip package 10.

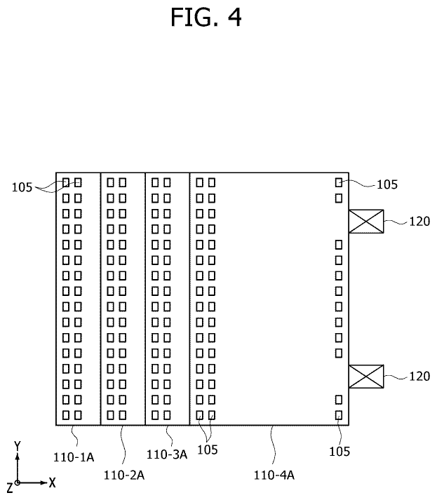

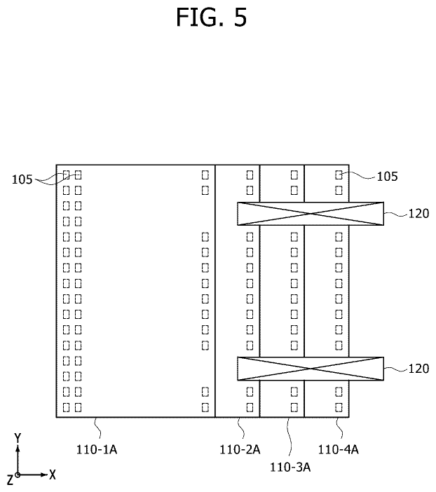

FIG. 4 and FIG. 5 illustrate top and bottom views, respectively, of a plurality of chips and a plurality of support structures 120, for example, as shown in FIG. 1. FIG. 4 shows a top view in the Z direction of a plurality of stacked chips 110-1A, 110-2A, 110-3A, and 110-4A and a plurality of support structures 120 in this example. FIG. 3 shows a bottom view in the Z direction of the plurality of stacked chips 110-1A, 110-2A, 110-3A, and 110-4A and the plurality of support structures 120 in this example.

Referring to FIG. 4 and FIG. 5, a plurality of connection structures 105 among the first chip 110-1A, the second chip 110-2A, the third chip 110-3A, and the fourth chip 110-4A are illustrated. As shown in FIG. 4, a section of the each of the support structures 120 extends beyond the fourth chip 110-4B in the X direction and is connected to the solder ball 101-8 through the connection structure 103 of the substrate 100 as shown in FIG. 1. According to this example, each of the support structures 120 is connected to a separate solder ball. As shown in FIG. 5, each of the support structures 120 supports the overhang of each of the second chip 110-2A, the third chip 110-3A, and the fourth chip 110-4A. A section of each of the support structures 120 extends beyond the fourth chip 110-4A in the X direction and is connected to the solder ball 101-8 through the connection structure 103 of the substrate 100 as shown in FIG. 1. Each of the support structures 120 supports the overhang of the second chip 110-2A, the overhang of the third chip 110-3B, and the overhang of the fourth chip 110-4B to prevent or reduce physical deformation of the second chip 110-2A, the third chip 110-3A, and the fourth chip 110-4A, and may be grounded or may be connected to a cooler or a heat sink through the solder ball 101-8 to dissipate heat generated by the first chip 110-1A, the second chip 110-2A, the third chip 110-3A, and the fourth chip 110-4A outside the multichip package 10. Optionally, the two support structures 120 may be different shapes, including different widths or lengths. More than two support structures 120 may be utilized. Bridges or connections between the support structures 120 may be provided in the Y direction, which bridges or connections may electrically and/or thermally connect the support structures 120.

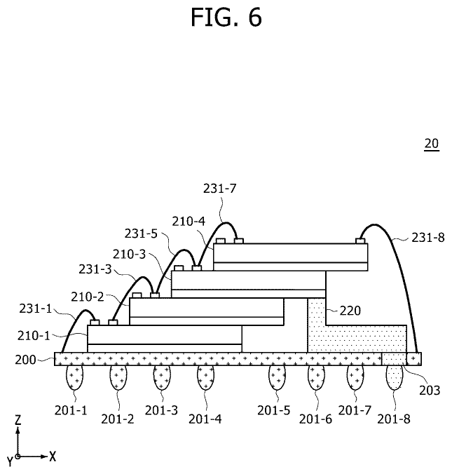

FIG. 6 illustrates a configuration of a multichip package 20 according to an embodiment of the present disclosure.

As shown in FIG. 6, the multichip package 20 includes a substrate 200, a first chip 210-1, a second chip 210-2, a third chip 210-3, a fourth chip 210-4, and a support structure 220.

The substrate 200 is supplied with a voltage through any of the solder balls 201-1 through 201-7, for example, a voltage from a source external to the multichip package 20. The substrate 200 includes a connection structure 203 connected to a solder ball 210-8. The substrate 200 may be connected to the ground voltage through the solder ball 201-8. One or more of the solder balls provides an external electrical connection for the substrate 200, for example, to a voltage, a ground voltage, or device external to the multichip package 20. The substrate 200 may be connected to devices external to the multichip package 20 such as a cooler or a heat sink, an electrostatic discharge protection device, and the like.

The first chip 210-1 is stacked over or on the substrate 200. The first chip 210-1 is electrically connected to the substrate 200 through bonding wire 231-1. The second chip 210-2 is stacked over or on the first chip 210-1. An overhang occurs because the second chip 210-2 is offset from the first chip 210-1 in the X direction, where a portion of the second chip 210-2 is not supported by the first chip 210-1 in the Z direction. The second chip 210-2 is electrically connected to the first chip 210-1 through bonding wire 231-3. The third chip 210-3 is stacked over or on the second chip 210-2. An overhang occurs because the third chip 210-3 is offset from the second chip 210-2 in the X direction, where a portion of the third chip 210-3 is not supported by the second chip 210-2 in the Z direction. The third chip 210-3 is electrically connected to the second chip 210-2 through bonding wire 231-5. The fourth chip 210-4 is stacked over or on the third chip 210-3. An overhang occurs because the fourth chip 210-4 is offset from the third chip 210-3 in the X direction, where a portion of the fourth chip 210-4 is not supported by the third chip 210-3 in the Z direction. The fourth chip 210-4 is electrically connected to the third chip 210-3 through bonding wires 231-7. The fourth chip 210-4 is electrically connected to the substrate 200 through bonding wire 231-8. The chips 210-1, 210-2, 210-3, and 210-4 are stacked in the Z direction.

The support structure 220 is disposed or connected between the third chip 210-3 and the substrate 200 to support the overhang of the third chip 210-3. The support structure 220 supports the overhang occurs where the third chip 210-3 is not supported by the second chip 210-2 in a region between the third chip 210-3 and the substrate 200. The support structure 220 supports the overhang of the third chip 210-3, such that physical deformation of at least the third chip 210-3 due to the overhang of the third chip 210-3 may be reduced or prevented.

The support structure 220 is connected to the solder ball 201-8 through the connection structure 203 of the substrate 200. The support structure 220 and the connection structure 203 may be advantageously made of a highly conductive material that conducts heat and electricity well. The third chip 210-3 may be connected to the ground voltage to be grounded through the support structure 220, the connection structure 203, and the solder ball 201-8. The third chip 210-3 may be connected to a cooler or a heat sink through the support structure 220, the connection structure 203, and the solder ball 201-8, such that heat generated by at least the third chip 210-3 is dissipated outside the multichip package 20.

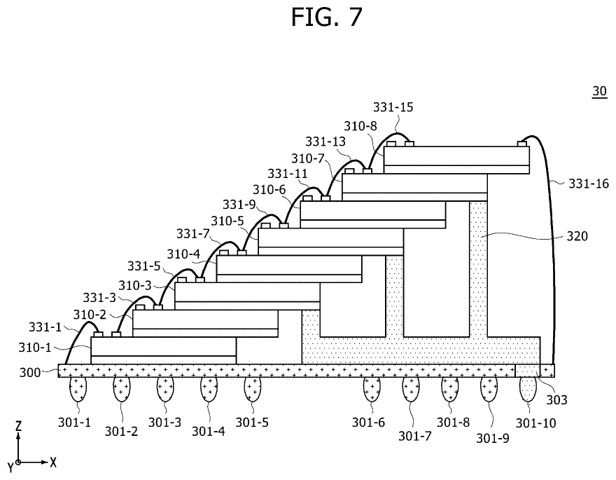

FIG. 7 illustrates a configuration of a multichip package 30 according to an embodiment of the present disclosure.

As shown in FIG. 7, the multichip package 30 includes a substrate 300, a first chip 310-1, a second chip 310-2, a third chip 310-3, a fourth chip 310-4, a fifth chip 310-5, a sixth chip 310-6, a seventh chip 310-7, an eighth chip 310-8, and a support structure 320.

The substrate 300 is supplied with a voltage through any of solder balls 301-1 through 301-9, for example, a voltage from a source external to the multichip package 30. The substrate 300 includes a connection structure 303 connected to a solder ball 301-10. The substrate 300 may be connected to the ground voltage through the solder ball 301-10. One or more of the solder balls provides an external electrical connection for the substrate 300, for example, to a voltage, a ground voltage, or device external to the multichip package 30. The substrate 300 may be connected to devices external to the multichip package 30 such as a cooler or heat sink, an electrostatic discharge protection device, and the like, for example, through the solder ball 301-10.

The first chip 310-1 is stacked over or on the substrate 300. The first chip 310-1 is electrically connected to the substrate 300 through bonding wire 331-1. The second chip 310-2 is stacked over or on the first chip 310-1. An overhang occurs because the second chip 310-2 is offset from the first chip 310-1 in an X direction, where a portion of the second chip 310-2 is not supported by the first chip 310-1 in the Z direction. The second chip 310-2 is electrically connected to the first chip 310-1 through bonding wire 331-3. The third chip 310-3 is stacked over or on the second chip 310-2. An overhang occurs because the third chip 310-3 is offset from the second chip 310-2 in the X direction, where a portion of the third chip 310-3 is not supported by the second chip 310-2 in the Z direction. The third chip 310-3 is electrically connected to the second chip 310-2 through bonding wire 331-5. The fourth chip 310-4 is stacked over or on the third chip 310-3. An overhang occurs because the fourth chip 310-4 is offset from the third chip 310-3 in the X direction, where a portion of the fourth chip 310-4 is not supported by the third chip 310-3 in the Z direction. The fourth chip 310-4 is electrically connected to the third chip 310-3 through bonding wire 331-7. The fifth chip 310-5 is stacked over or on the fourth chip 310-4. An overhang occurs because the fifth chip 310-5 is offset from the fourth chip 310-4 in the X direction, where a portion of the fifth chip 310-5 is not supported by the fourth chip 310-4 in the Z direction. The fifth chip 310-5 is electrically connected to the fourth chip 310-4 through bonding wire 331-9. The sixth chip 310-6 is stacked over or on the fifth chip 310-5. An overhang occurs because the sixth chip 310-6 is offset from the fifth chip 310-5 in the X direction, where a portion of the sixth chip 310-6 is not supported by the fifth chip 310-5 in the Z direction. The sixth chip 310-6 is electrically connected to the fifth chip 310-5 through bonding wire 331-11. The seventh chip 310-7 is stacked over or on the sixth chip 310-6. An overhang occurs because the seventh chip 310-7 is offset from the sixth chip 310-6 in the X direction, where in which a portion of the seventh chip 310-7 is not supported by the sixth chip 310-6 in the Z direction. The seventh chip 310-7 is electrically connected to the sixth chip 310-6 through bonding wire 331-13. The eighth chip 310-8 is stacked over or on the seventh chip 310-7. An overhang occurs because the eighth chip 310-8 is offset from the seventh chip 310-7 in the X direction, where a portion of the eighth chip 310-8 is not supported by the seventh chip 310-7 in the Z direction. The eighth chip 310-8 is electrically connected to the seventh chip 310-7 through bonding wire 331-15. The eighth chip 310-8 is electrically connected to the substrate 300 through bonding wire 331-16. The chips 310-1, 310-2, 310-3, and 310-4, 310-5, 310-6, 310-7, and 310-8 are stacked in the Z direction.

The support structure 320 is disposed or connected between the substrate 300 and the third chip 310-3, the fifth chip 310-5, and the seventh chip 310-7 to support the overhang of each of the third chip 310-3, the fifth chip 310-5, the seventh chip 310-7. The support structure 320 supports the overhang where the third chip 310-3 is not supported by the second chip 310-2 in a region between the third chip 310-3 and the substrate 300. The support structure 320 supports the overhang where the fifth chip 310-5 is not supported by the fourth chip 310-4 in a region between the fifth chip 310-5 and the substrate 300. The support structure 320 supports the overhang where the seventh chip 310-7 is not supported by the sixth chip 310-6 in a region between the seventh chip 310-7 and the substrate 300. The support structure 320 supports the overhang of each of the third chip 310-3, the fifth chip 310-5, and the seventh chip 310-7, such that physical deformation of at least the third chip 310-3, the fifth chip 310-5, and the seventh chip 310-7 due to the overhang of the third chip 310-3, the overhang of the fifth chip 310-5, and the overhang of the seventh chip 310-7 may be reduced or prevented.

The support structure 320 is connected to the solder ball 301-10 through the connection structure 303 of the substrate 300. The support structure 320 and the connection structure 303 may be advantageously made of a highly conductive material that conducts heat and electricity well. Each of the third chip 310-3, the fifth chip 310-5, and the seventh chip 310-7 may be connected to the ground voltage to be grounded through the support structure 320, the connection structure 303, and the solder ball 301-10. Each of the third chip 310-3, the fifth chip 310-5, and the seventh chip 310-7 may be connected to a cooler or a heat sink through the support structure 320, the connection structure 303, and the solder ball 301-10 to dissipate heat generated by at least the third chip 310-3, the fifth chip 310-5, and the seventh chip 310-7 outside the multichip package 30.

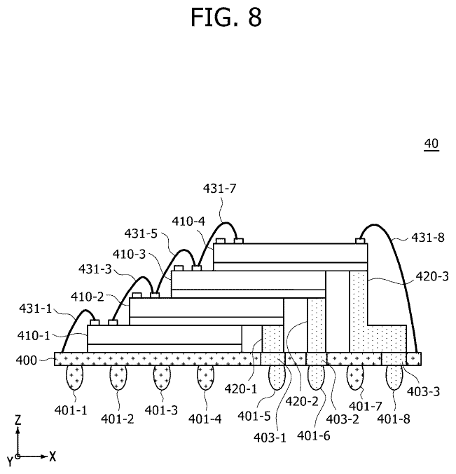

FIG. 8 illustrates a configuration of a multichip package 40 according to an embodiment of the present disclosure.

As shown in FIG. 8, the multichip package 40 includes a substrate 400, a first chip 410-1, a second chip 410-2, a third chip 410-4, a fourth chip 410-4, a first support structure 420-1, a second support structure 420-2, and a third support structure 420-3. The substrate 400 is supplied with a voltage through any of solder balls 401-1 through 401-4 and 401-7, for example, a voltage from a source external to the multichip package 40. The substrate 400 includes a first connection structure 403-1 connected to a solder ball 401-5, a second connection structure 403-2 connected to a solder ball 401-6, and a third connection structure 403-3 connected to a solder ball 401-8. The substrate 400 may be connected to the ground voltage, for example, through the solder balls 401-5, 401-6, 401-8. One or more of the solder balls provides an external electrical connection for the substrate 400, for example, to a voltage, a ground voltage, or device external to the multichip package 40. The substrate 400 may be connected to devices external to the multichip package 40 such as a cooler or heat sink, an electrostatic discharge protection device, and the like through the solder balls 401-5, 401-6, 401-8.

The first chip 410-1 is stacked over or on the substrate 400. The first chip 410-1 is electrically connected to the substrate 400 through bonding wire 431-1. The second chip 410-2 is stacked over or on the first chip 410-1. An overhang occurs because the second chip 410-2 is offset from the first chip 410-1 in an X direction, where a portion of the second chip 410-2 is not supported by the first chip 410-1 in the Z direction. The second chip 410-2 is electrically connected to the first chip 410-1 through bonding wire 431-3. The third chip 410-3 is stacked over or on the second chip 410-2. An overhang occurs because the third chip 410-3 is offset from the second chip 410-2 in the X direction, where a portion of the third chip 410-3 is not supported by the second chip 410-2 in the Z direction. The third chip 410-3 is connected to the second chip 410-2 through bonding wire 431-5. The fourth chip 410-4 is stacked over or on the third chip 410-3. An overhang occurs because the fourth chip 410-4 is offset from the third chip 410-3 in the X direction, where a portion of the fourth chip 410-4 is not supported by the third chip 410-3 in the Z direction. The fourth chip 410-4 is electrically connected to the third chip 410-3 through bonding wire 431-7. The fourth chip 410-4 is electrically connected to the substrate 400 through bonding wire 431-8.

The chips 410-1, 410-2, 410-3, and 410-4 are stacked in the Z direction.

The first support structure 420-1 supports the overhang where the second chip 410-2 is not supported by the first chip 410-1 in a region between the second chip 410-2 and the substrate 400. The second support structure 420-2 supports the overhang where the third chip 410-3 is not supported by the second chip 410-2 in a region between the third chip 410-3 and the substrate 400. The third support structure 420-3 supports the overhang where the fourth chip 410-4 is not supported by the third chip 410-3 in a region between the fourth chip 410-4 and the substrate 400. The first support structure 420-1, the second support structure 420-2, and the third support structure 420-3 support the overhang of the second chip 410-2, the overhang of the third chip 420-3, and the overhang of the fourth chip 410-4, respectively, such that physical deformation of at least the second chip 410-2, the third chip 410-3, and the fourth chip 410-4 due to the overhangs of the second chip 410-2, the third chip 410-3, and the fourth chip 410-4 may be reduced or prevented.

The first support structure 420-1, the second support structure 420-2, and the third support structure 420-1 through 420-3 are connected to the solder balls 401-5, 401-6, and 401-8 through the first connection structure 403-1, the second connection structure 403-2, and the third connection structure 403-3, respectively. Each of the support structures 420-1 through 420-3 and each of the connection structures 403-1 through 403-3 may be advantageously formed of a highly conductive material that conducts heat and electricity well. The second chip 410-2, the third chip 410-3, and the fourth chip 410-4 may be connected to the ground voltage to be grounded through the support structures 420-1 through 420-3, the connection structures 403-1 through 403-3, and the solder balls 401-5, 401-6, and 401-8, respectively. The second chip 410-2, the third chip 410-3, and the fourth chip 410-4 may be connected to a cooler or a heat sink through the support structures 420-1 through 420-3, the connection structures 403-1 through 403-3, and the solder balls 401-5, 401-6, and 401-8, respectively, to dissipate heat generated by the first chip 410-1, the second chip 410-2, the third chip 410-3, and the fourth chip 410-4 outside the multichip package 40.

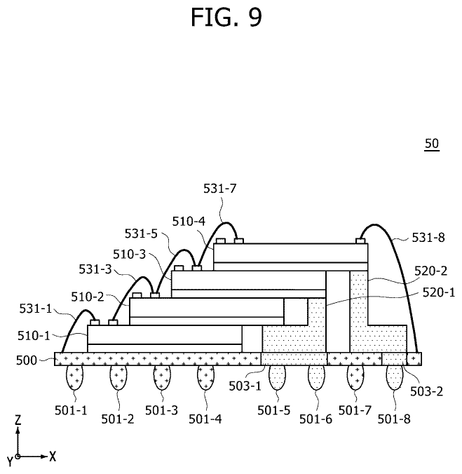

FIG. 9 illustrates a configuration of a multichip package 50 according to an embodiment of the present disclosure.

As shown in FIG. 9, the multichip package 50 includes a substrate 500, a first chip 510-1, a second chip 510-2, a third chip 510-3, a fourth chip 510-4, a first support structure 520-1, and a second support structure 520-2.

The substrate 500 is supplied with a voltage through any of solder balls 501-1 through 501-4 and 501-7, for example, a voltage from a source external to the multichip package 50. The substrate 500 includes a first connection structure 503-1 connected to solder balls 501-5 and 501-6 and a second connection structure 503-2 connected to a solder ball 501-8. One or more of the solder balls provides an external electrical connection for the substrate 500, for example, to a voltage, a ground voltage, or device external to the multichip package 50. The substrate 500 may be connected to the ground voltage, for example, through the solder balls 501-5, 501-6, and 501-8. The substrate 500 may be connected to devices external to the multichip package 40 such as a cooler or heat sink, an electrostatic discharge (ESD) protection device, and the like.

The first chip 510-1 is stacked over or on the substrate 500. The first chip 510-1 is electrically connected to the substrate 500 through bonding wire 531-1. The second chip 510-2 is stacked over or on the first chip 510-1. An overhang occurs because the second chip 510-2 is offset from the first chip 510-1 in an X direction, where a portion of the second chip 510-2 is not supported by the first chip 510-1 in the Z direction. The second chip 510-2 is electrically connected to the first chip 510-1 through bonding wire 531-3. The third chip 510-3 is stacked over or on the second chip 510-2. An overhang occurs because the third chip 510-3 is offset from the second chip 510-2 in the X direction, where a portion of the third chip 510-3 is not supported by the second chip 510-2 in the Z direction. The third chip 510-3 is electrically connected to the second chip 510-2 through bonding wire 531-5. The fourth chip 510-4 is stacked over or on the third chip 510-3. An overhang occurs because the fourth chip 510-4 is offset from the third chip 510-3 in the X direction, where a portion of the fourth chip 510-4 is not supported by the third chip 510-3 in the Z direction. The fourth chip 510-4 is electrically connected to the third chip 510-3 through bonding wire 531-7. The fourth chip 510-4 is electrically connected to the substrate 500 through bonding wire 531-8. The chips 510-1, 510-2, 510-3, and 510-4 are stacked in the Z direction.

The first support structure 520-1 supports the overhang of the second chip 510-2 where the second chip 510-2 is not supported by the first chip 510-1 in a region between the second chip 310-2 and the substrate 500 and supports the overhang of the third chip 510-3 where the third chip 510-3 is not supported by the second chip 510-2 in a region between the third chip 310-2 and the substrate 500. The second support structure 520-2 supports the overhang where the fourth chip 510-4 is not supported by the third chip 510-3 in a region between the fourth chip 510-4 and the substrate 500. The first support structure 520-1 and the second support structure 520-2 support the overhangs of the second chip 510-2, the third chip 520-3, and the fourth chip 510-4, such that physical deformation of at least the second chip 510-2, the third chip 510-3, and the fourth chip 510-4 due to the overhangs of the second chip 510-2, third chip 510-3, and fourth chip 510-4 may be reduced or prevented.

The support structures 520-1 and 520-2 are connected to the solder balls 501-5, 501-6, and 501-8 through the connection structures 503-1 and 503-2. Each of the support structures 520-1 and 520-2 and each of the connection structures 503-1 and 503-2 may be advantageously formed of a highly conductive material that conducts heat and electricity well. The second chip 510-2, the third chip 610-3, and the fourth chip 610-4 may be connected to the ground voltage to be grounded through the support structures 520-1 and 520-2, the connection structures 503-1 and 503-2, and the solder balls 501-5, 501-6, and 501-8. The second chip 510-2, the third chip 510-3, and the fourth chip 510-4 may be connected to a cooler or a heat sink through the support structures 520-1 and 520-2, the connection structures 503-1 and 503-2, and the solder balls 501-5, 501-6, and 501-8, to dissipate heat generated by the first chip 510-1, the second chip 510-2, the third chip 510-3, and the fourth chip 510-4 outside the multichip package 50.

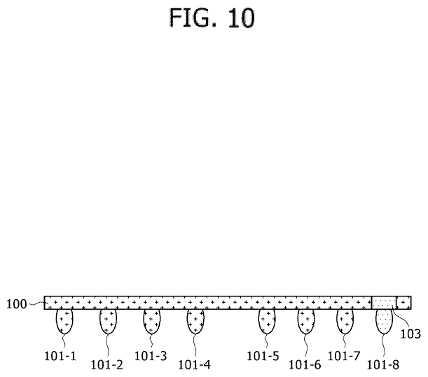

FIG. 10 through FIG. 13 illustrate views of a multichip package formed utilizing a method of forming a multichip package 10 according to an embodiment of the present disclosure.

As shown in FIG. 10, a substrate 100 connected to solder balls 101-1 through 101-8 is prepared or formed. One or more of the solder balls 101-1 through 101-7 provides an external electrical connection for the substrate 100, for example, to a voltage, a ground voltage, or device external to the multichip package 10. The substrate 100 includes a first connection structure 103 connected to the solder ball 101-8 that provides an external electrical connection for the substrate 100, for example, to the ground voltage or devices external to the multichip package 10 such as a cooler or heat sink, an electrostatic discharge (ESD) protection device, and the like.

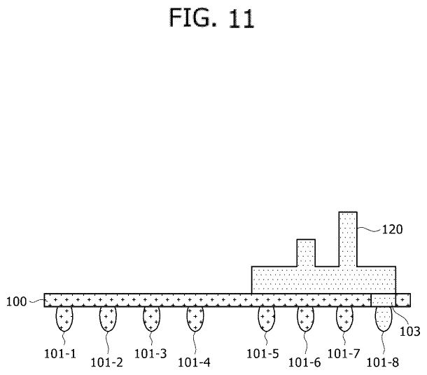

As shown in FIG. 11, a support structure 120 is formed over or on the substrate 100. The support structure 120 is electrically connected to the solder ball 101-8 through the connection structure 103.

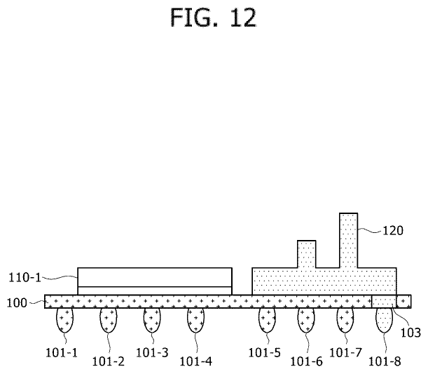

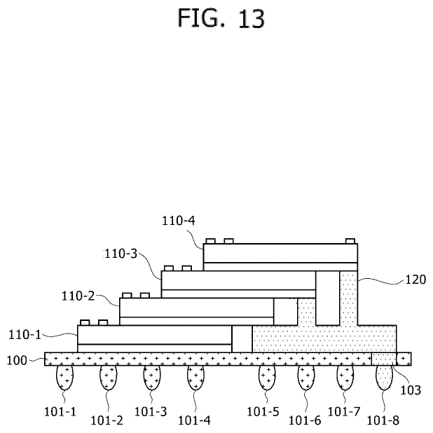

As shown in FIG. 12 and FIG. 13, a first chip 110-1 is stacked over or on the substrate 100, a second chip 110-2 is stacked over or on the first chip 110-1, a third chip 110-3 is stacked over or on the second chip 110-2, and a fourth chip 110-4 is stacked over or on the third chip 110-3. As shown in FIG. 13, the second chip 110-2, the third chip 110-3, and the fourth chip 110-4 are stacked over or on the first chip 110-1, the second chip 110-2, and the third chip 110-3, respectively, such that an overhang results where a portion of the second chip 110-2 is not supported by the first chip 110-1, an overhang results where a portion of the third chip 110-3 is not supported by the second chip 110-2, and an overhang results where a portion of the fourth chip 110-4 is not supported by the third chip 110-3. The overhang of the second chip 110-2, the overhang of the third chip 110-3, and the overhang of the fourth chip 110-4 are supported by the support structure 120. Because the overhangs of the second chip 110-2, the third chip 110-3, and the fourth chip 110-4 are supported by the support structure 120, physical deformation of the second chip 110-2, the third chip 110-3, and the fourth chip 110-4 due to the overhangs of the second chip 110-2, the third chip 110-3, and the fourth chip 110-4 may be reduced or prevented.

The multichip package 20 shown in FIG. 6, the multichip package 30 shown in FIG. 7, the multichip package 40 shown in FIG. 8, and the multichip package 50 shown in FIG. 9 may be formed using the method of forming the multichip package 10 described with respect to FIG. 10 through FIG. 13. Different quantities of chips and different quantities of support structures than those shown in the examples described may be utilized in any combination of chips and support structures.

Concepts are disclosed in conjunction with examples and embodiments as described above. Those skilled in the art will understand that various modifications, additions, and substitutions are possible without departing from the scope and technical spirit of the present disclosure. Accordingly, the embodiments disclosed in the present specification should be considered from an illustrative standpoint and not a restrictive standpoint. Therefore, the scope of the present disclosure is not limited to the above descriptions. All changes within the meaning and range of equivalency of the claims scope are included within their scope.

What is claimed is:

1. A multichip package comprising:
a substrate connected to a plurality of solder balls including a first solder ball;
a first chip stacked over the substrate;
a second chip stacked over the first chip and including a first overhang not supported by the first chip; and
a support structure supporting the first overhang and connected to the first solder ball that provides an external electrical connection to the substrate for a voltage external to the substrate.

2. The multichip package of claim 1, wherein the external electrical connection provides access to a ground voltage and a voltage different from the ground voltage.

3. The multichip package of claim 1, wherein the support structure comprises a plurality of support structures supporting the first overhang in at least one region between the substrate and the first overhang.

4. The multichip package of claim 1, further comprising a third chip stacked over the second chip and including a second overhang not supported by the second chip.

5. The multichip package of claim 4, wherein the support structure supports the second overhang.

6. The multichip package of claim 5, wherein the support structure comprises a plurality of support structures supporting the second overhang in at least one region between the substrate and the second overhang.

7. The multichip package of claim 4, further comprising a fourth chip stacked over the third chip and including a third overhang not supported by the third chip.

8. The multichip package of claim 7, wherein the support structure supports at least one of the second overhang and the third overhang.

9. The multichip package of claim 8, wherein the support structure comprises a plurality of support structures supporting the third overhang in at least one region between the substrate and the third overhang.

10. A multichip package comprising:
a substrate connected to a plurality of solder balls including a first solder ball;
a first chip stacked over the substrate;
a second chip stacked over the first chip and including a first overhang not supported by the first chip; and
a support structure supporting the first overhang and connected to the first solder ball that provides an external electrical connection for a device external to the substrate.

11. The multichip package of claim 10, wherein the external electrical connection provides access to a device external to the multichip package, wherein the device is a cooler, heat sink, or an electrostatic discharge (ESD) protection device.

12. The multichip package of claim 10, wherein the support structure comprises a plurality of support structures supporting the first overhang in at least one region between the substrate and the first overhang.

13. The multichip package of claim 10, further comprising a third chip stacked over the second chip and including a second overhang not supported by the second chip, wherein the support structure supports the second overhang.

14. The multichip package of claim 10, wherein the support structure comprises a plurality of support structures supporting the second overhang in at least one region between the substrate and the second overhang.

15. The multichip package of claim 10, further comprising:
a third chip stacked over the second chip and including a second overhang not supported by the second chip; and
a fourth chip stacked over the third chip and including a third overhang not supported by the third chip.

16. The multichip package of claim 15, wherein the support structure supports at least one of the second overhang and the third overhang.

17. The multichip package of claim 16, wherein the support structure comprises a plurality of support structures supporting the second overhang in at least one region between the substrate and the second overhang and the third overhang in at least one region between the substrate and the third overhang.

18. A multichip package comprising:
a substrate connected to a plurality of solder balls including a first solder ball and a second solder ball;
a first chip stacked over the substrate;
a second chip stacked over the first chip and including a first overhang not supported by the first chip;
a third chip stacked over the second chip and including a second overhang not supported by the second chip;
a first support structure supporting the first overhang and connected to the first solder ball that provides a first external electrical connection for the substrate; and
a second support structure supporting the second overhang and connected to the second solder ball that provides a second external electrical connection for the substrate.

19. A multichip package comprising:
a substrate connected to a plurality of solder balls including a first solder ball and a second solder ball;
a first chip stacked over the substrate;
a second chip stacked over the first chip and including a first overhang not supported by the first chip;
a third chip stacked over the second chip and including a second overhang not supported by the second chip;
a fourth chip stacked over the third chip and including a third overhang not supported by the third chip;
a first support structure supporting the first overhang and the second overhang and connected to the first solder ball that provides an external electrical connection to the substrate for a first voltage; and
a second support structure supporting the third overhang and connected to the second solder ball that provides an external electrical connection to the substrate for a second voltage.

20. A method of forming a multichip package, the method comprising:
preparing a substrate connected to a plurality of solder balls;
forming a support structure over the substrate, wherein the support structure is connected an external electrical connection for the substrate;
stacking a first chip over the substrate; and
stacking a second chip over the first chip and the support structure,
wherein an overhang of the second chip is not supported by the first chip and is supported by the support structure.

21. A multichip package comprising:
a substrate;
a first chip stacked over the substrate;
a second chip stacked over the first chip, wherein the second chip is offset from the first chip in a first direction resulting in an overhang; and
a support structure disposed between the overhang and the substrate and electrically connected to an external electrical connection for the substrate.
